(19) United States
(12) Patent Application Publication
(10) Pub. No.: US 2023/0090894 A1
(43) Pub. Date: Mar. 23, 2023

(54) Method for Manufacturing a Metal-Polymer Hybrid Part and Metal-Polymer Hybrid Part

(71) Applicant: BASF SE, Ludwigshafen am Rhein (DE)

(72) Inventors: Roman BEM, Ludwigshafen (DE); Patrick SPIES, Ludwigshafen (DE)

(21) Appl. No.: 17/999,079

(22) PCT Filed: May 17, 2021
(86) PCT No.: PCT/EP2021/063011

§ 371 Date: Nov. 17, 2022

(30) Foreign Application Priority Data
May 19, 2020 (EP) 20175452.0

(51) Int. Cl. B29C 65/16; H05K 9/00; H05K 7/20; B32B 15/088; B29C 65/00

(52) U.S. Cl. CPC B29C 65/1635; H05K 9/0007; H05K 7/2039; B32B 15/088; B29C 65/1677; B29C 66/72321; B29C 65/1616

(57) ABSTRACT

Disclosed herein are a method for manufacturing a metal-polymer hybrid part, the metal-polymer hybrid part itself, and a laminate component. The method includes the steps of (a) providing a laminate component containing at least one metallic layer covered by at least one first functional layer, (b) providing a polymeric component, (c) bringing into contact the polymeric component with the at least one first functional layer of the laminate component, (d) joining the polymeric component onto the at least one first functional layer by physical treatment and (e) obtaining the metal-polymer hybrid part.

The present invention relates to a method for manufacturing a metal-polymer hybrid part, the metal-polymer hybrid part itself as well as a laminate component.

For electric or electronic components as well as mechanical structures, housings are often used consisting of a polymer compound part, which in particular has a thermoplastic matrix, and a polymer metal hybrid, wherein the different materials take over different functions. The polymer metal hybrid as a semi-finished product is suitable for an electromagnetic shielding, as a diffusion barrier, for instance against oil, fuel and cooling media for electronic housings, for heat dissipation from the housing interior as well as for abrasion protection. The polymer compound part serves for the structure and outer contour and enables forming of geometric complex structures for connecting to other structures as well as for receiving and positioning of electronic elements or plugs. Therefore, polymer metal hybrids are generally known from the state of the art.

For instance, DE 10 2004 045 402 A1 describes an injection moulded plastic supporting part, which has a metallic coating that forms a part of the moulding. The coating can be located on two sides of the supporting part and is pre-formed before placing in the injection tool. Further, a process for manufacturing the component is described in which a) a metal foil forming a coating is placed in an injection moulding tool, is fixed in position and the tool is closed and b) plastic material is injected into the tool and bonds onto the coating to form a supporting part.

Furthermore, from DE 103 61 096 A1 a component and a method for manufacturing a component are known. The component is formed at least in part from metal, the metallic region being at least partially encapsulated by injection-moulded thermoplastic material. Between the plastic and the metallic region there is arranged at least in some areas an adhesion promoting layer consisting of a thermoplastic material at least on its side facing the plastic, by means of which a non-positive connection is present between the metallic region and the plastic. The adhesion promoting layer is applied to at least part of the metallic region, wherein at least one non-positive connection is formed between the adhesion promoter layer and the metallic region. Subsequently, the plastic is moulded on in such a way that at least the surface region facing the plastic of the bonding agent layer arranged on the metallic region is melted by the plasticized plastic and welded to the sprayed-on plastic at least in some regions.

In addition, DE 10 2018 207 205 A1 is related to a hybrid component, in particular a housing or a housing part, in a metal/plastic composite, which contains at least one metal sheet shielding against electromagnetic radiation, dynamic or static electric and/or dynamic or static magnetic fields and at least one thermoplastic material applied to the metal sheet in a material-locking and/or form-locking manner, thermosetting (duroplastic) or elastomeric plastic layer. This hybrid component characterised in that it has a shielding factor S(v) of 1.00 dB to 120.00 dB at a dynamic magnetic field or a dynamic electromagnetic field with a frequency v of 0.001 kHz up to 1,000 kHz, wherein the shielding factor S(v) is calculated from the quotient of the field strength measured at the location of the sink with or without a hybrid component located between the sink and the source. Furthermore, this prior art relates to a process for producing the hybrid component and its use.

According to the state of the art, the joining of metal components and polymeric components in PMH structures (PMH: polymer metal hybrids) can be carried out in different ways. Both components can be joined with a glue which, however, adds another material class to the overall system as well as another process step and results in longer cycle times due to hardening of the glue. Another possibility is the application of a bonding agent/primer which, however, has a poor operational stability due to thermal tensions because of different Coefficients of Linear Thermal Expansion (CLTE) and the relatively thin boundary layer between metal and polymer. Other attempts are based on form-locking joints which, however, have geometrical limitations because of the injection moulding tool. Furthermore, hollow bodies are not processable with this technique. A further possibility is an over-moulding of the metal part with the polymer in an injection moulding process. Finally, fastening elements like screws or bolts can be used which, however, also introduce an additional material class and an additional process step in manufacturing.

The processes and components referred to above have some drawbacks, for instance expensive moulds and complex process handling as well as differing CLTE behaviour for over-moulding or long curing and hardening times in case of gluing.

Therefore, there is a need for an advanced manufacturing method and advanced polymer metal hybrids which overcome the above-mentioned drawbacks.

It is the aim of the present invention to provide an advanced method for manufacturing a metal-polymer hybrid part as well as the metal-polymer hybrid part itself which exhibit enhanced joining stability as well practical applicability. It is another aim of the present invention to provide a laminate component of metal and polymer which can be processed by well-known metal working techniques.

The above-mentioned task is solved in a first aspect of the present invention by a method for manufacturing a metal-polymer hybrid part comprising the steps of
a) providing a laminate component (1) containing at least one metallic layer (101) covered by at least one first functional layer (103),
b) providing a polymeric component (3),
c) bringing into contact the polymeric component (3) with the at least one first functional layer (103) of the composite component (1),
d) joining the polymeric component (3) onto the at least one first functional layer (103) by physical treatment and
e) obtaining the metal-polymer hybrid part.

In addition, the above-mentioned task is solved in a second aspect of the present invention by a metal-polymer hybrid part, obtainable by the invented method detailed herein.

Further, the above-mentioned task is solved in a third aspect of the present invention by a laminate component (1), comprising
at least one metallic layer (101) and
at least one first functional layer (103) covering the at least one metallic layer (101), wherein the at least one first functional layer (103) comprises at least in part a laser-absorbing filler material.

By means of the present invention, metal-polymer hybrid parts are attainable, which can be further processed by standard metal working steps. In manufacturing the same, single well-known steps, for instance out of standard film lamination or standard joining technologies, can be used. The invented metal-polymer hybrid parts can be used for support engineering plastics and represent a novel grade of metal sheet coating. The invented metal-polymer hybrid parts are therefore in particular suitable for lightweight construction in automotive industry.

It is of further advantage that according to the present invention the polymeric component (3) can be produced in a standard injection moulding process. Short cycle time and other injection moulding parameters can properly be selected to obtain a polymeric component (3) with ideal properties. Moreover, the joining between the polymeric component (3) and the laminate component (1) can be done with a short cycle time. Joining can take place later in the production chain (e.g. during final assembly). Thus, the laminate component (1) may be produced in a metalworking company or workshop, whereas the polymeric component (3) can be fabricated on an injection moulding machine.

In addition, an increased efficiency can be obtained by modularisation. The laminate component (1) represents a uniform part and can be combined with different types of polymeric components (3). A metal press could work with several injection moulding machines in one cycle. Further, the present invention provides a high degree of geometrical freedom of the components, since no consideration would have to be given to demoulding, undercuts, rib height, and other aspects of mould design.

The invention is described in detail below.

If features are mentioned in the following description of the metal-polymer hybrid part and/or the laminate component (1) according to the invention, they also refer to the method according to the invention as described herein. Likewise, features which are mentioned in the description of the method according to the invention also refer to the metal-polymer hybrid part and/or the laminate component (1) according to the invention.

In a first aspect, the present invention relates to a method for manufacturing a metal-polymer hybrid part comprising the steps of
a) providing a laminate component (1) containing at least one metallic layer (101) covered by at least one first functional layer (103),
b) providing a polymeric component (3),
c) bringing into contact the polymeric component (3) with the at least one first functional layer (103) of the laminate component (1),
d) joining the polymeric component (3) onto the at least one first functional layer (103) by physical treatment and
e) obtaining the metal-polymer hybrid part.

The expression “metal-polymer hybrid part” designates, in the sense of the present invention, a part which is composed of a metal-polymer laminate structure and a polymer part joined together.

The term “laminate component” is used for a component which contains at least two layers, one of metal and one of polymer, wherein these layers as well as the laminate component have a thickness which is far below the width and length dimensions thereof (semi two-dimensional).

The polymeric component (3) may be a pure polymeric part but could also contain non-polymeric ingredients like fillers, strengtheners, pigments and the like. The material of the polymeric component (3) is a thermoplastic material and can preferably be selected from thermoplastic polyurethane (TPU) and polyamide, in particular especially from PA6, PA66, PA6/66, PA66/6, PA6T/6, PA6.10, PA6.12, PA12; PA9T, PA61/6T, PA6T/61, PA6/6.36 or combinations thereof. In particular applicable are polyether block polyamides such as copolymerisates of polyether diamines and aliphatic dicarboxylic acids (C₄-C₄₀) and/or lactams (C₆-C₁₂) like caprolactam or lauryllactam, copolymerisates of aliphatic diamines (C₄-C₁₀) and aliphatic dicarboxylic acids (C₄-C₄₀), polycondensates of lactams (C₆-C₁₂), copolymerisates of lactams and/or aliphatic dicarboxylic acids and aliphatic diamines or combinations thereof.

The polymeric component (3) may contain further additives such as glass fibre, carbon fibre, aramid fibres or combinations thereof. These fibres can be incorporated as roving or cuttings in the usual commercial form. Furthermore, woven fabrics, scrims, flow, mats and staple fibres made of the above-mentioned reinforcing materials can also be used.

Furthermore, the polymeric component (3) may also contain impact modifiers such as maleic anhydride grafted copolymers of ethylene and α-olefins and/or acrylic acid esters and/or acrylic acid, copolymers of maleic anhydride and ethylene and/or acrylic acid esters, styrene maleic anhydride (SMA), maleic anhydride grafted polypropylene.

In general, the at least one first functional layer (103) may comprise any thermoplastic polymer. Preferred polymers are given below.

The metallic layer (101) preferably may have a thickness of 0.01 mm to 2.0 mm. As the material, aluminium, steel, hot-dip galvanized steel or electro-galvanized steel are particularly preferred. The metallic layer (101) is adjusted to be deep-drawable.

In a particular embodiment, the metallic layer (101) may be pre-treated with an adhesion promoter/primer based on polyacrylic acid, polymethacrylic acid, polyacrylates or polymethacrylates, polyvinyl amines, phosphoric acids, polyphosphoric acid, copolymers of maleic acid and acrylic acid and/or methacrylic acids and/or ester of acrylic or methacrylic esters, copolymers of maleic acid and styrene, copolymers of ethylene and acrylic acid and/or methacrylic acids and/or esters of acrylic acid or methacrylic acid and/or maleic acid and polyvinylpyrrolidone, to ensure good bonding to the first functional layer (103) and/or a second functional layer (105). The adhesion promoter/primer is typically applied as aqueous solution via roll coating.

In step a) of the method according to the present invention, the laminate component (1), which contains at least one metallic layer (101) which is covered by at least one first functional layer (103) is provided. The expression “covered” is to be understood in that the metallic layer (101) is covered at least in part or even totally by the at least one first functional layer (103).

The laminate component (1) can be provided in different shapes for instance as a semi two-dimensional sheet or as a three-dimensional structure which can be obtained for instance by deep drawing or the like.

In step b), a polymeric component (3) is provided which in turn can be a flat part or as well a three-dimensional structure.

In step c), the polymeric component (3) is brought into contact with the at least one first functional layer (103) of the laminate component (1), which in particular means that the polymeric component (3) is put on top of at least a part of the functional layer (103). The at least one metallic layer (101) is located on the opposite side of the polymeric component (3).

In step d) the polymeric component (3) is joined onto the at least one first functional layer (103) by physical treatment, whereby in step e) the metal-polymer hybrid part is obtained.

By means of the present invention, metal-polymer hybrid parts are attainable, which can be further processed by standard metal working steps.

As can be seen, in the manufacturing, single well-known steps, for instance out of standard film lamination or standard joining technologies, are combined in a hitherto unknown manner. The metal-polymer hybrid parts manufactured according to the invented method can be used for support engineering plastics and represent a novel grade of metal sheet coating.

In a preferred embodiment of the present invention, the method for manufacturing a metal-polymer hybrid part is directed to form a housing, wherein the laminate component (1) is a three-dimensional part having a first cavity (la), wherein the polymeric component (3) is either a more or less flat part or also a three-dimensional part having a second cavity (3a), wherein the joining of both the polymeric component (3) and the laminate component (1) result in a metal-polymer hybrid part which encloses the cavities (la, 3a) and thereby forms a hollow space (5). Within the hollow space (5), for instance an electronic part can be located which is protected and/or shielded by the invented metal-polymer hybrid part.

The invented laminate component (1) as a three-dimensional part can be obtained by metal working techniques such as deep drawing, stretch forming, blow or roll forming as well as stamping, in particular by cold forming. Thereby, the final or a preliminary shape of the final geometry is set.

The polymeric component (3) according to the present invention can be obtained by a suitable forming technique such as injection moulding, extrusion moulding, deep drawing or blow moulding. The polymeric component (3) may be embodied as a reinforcing rib, a screw dome or a housing element with radio integration.

In a further development of the inventive method, a physical treatment comprises laser transmission welding, ultra-sonic welding, friction welding and/or thermal melt joining.

In case of ultra-sonic welding or friction welding, the generation of thermal energy is effected by internal or external friction between and or within in the joining partners, i.e. the polymeric component (3) and the first functional layer (103). The heat input is executed by radiation, by contact or by convection in the end faces polymeric component (3) and the first functional layer (103). The joining can take place by pressing the molten surfaces together.

By one of these physical treatments the contact faces of the polymeric component (3) on the first functional layer (103) are softened and/or melted at least in part such that both polymeric materials can be joined.

In a very particular embodiment of the invented method, the material of the polymeric component (3) it is at least in part translucent (i.e. the part brought into contact with the first functional layer (103)). This at least part of the polymeric component (3) is in particular, laser transmitting. In this particular embodiment, the physical treatment comprises laser transmission welding.

By applying this particular embodiment, a laser beam (L) is directed to those parts of the polymeric component (3) which are facing the first functional layer (103) such that the laser energy is transmitted at least in part through the polymeric component (3) into the first functional layer (103). Thereby, at least the boundary layers of both the polymeric components (3) and the first functional layer (103) are melted or softened in order to undergo a joining.

In order to enhance the receipt of energy within the first functional layer (103), the laminate component (1) exhibits at least in part a laser absorbing property.

Although the laser absorbing property can be located on the boundary layer between the metallic layer (101) and the first functional layer (103), it is particularly preferred that the laser absorbing property is located within the first functional layer (103).

In a very particular embodiment of the present invention, the joint between the laminate component (1) and the polymeric component (3) is formed, wherein the joint is at least in part substance-locking. In other words, due to the softening/melting of the boundary layers between the polymeric component (3) and the first functional layer (103) a mixing at least that the atomic level is effected such that both polymeric materials are joined.

Another embodiment of the present invention is directed to the case wherein the at least one metallic layer (101) is covered by at least one second functional layer (105) opposite to the at least one first functional layer (103).

In this embodiment, a polymer/metal/polymer sandwich structure is provided as the laminate component (1). This opens the possibility of applying another polymeric component (3) onto the opposite side, for instance.

In another further development, the at least one metallic layer (101) is in substance-locking contact with the at least one first functional layer (103) and/or the at least one second functional layer (105).

The term “substance-locking” describes a joint in which the joining partners are held together by atomic forces or molecular forces. At the same time, substance-locking joints can only be separated by destroying the joint itself. Substance-locking joints can be attained for instance by soldering, welding, gluing or vulcanising.

In this particular embodiment, an intermediate layer is provided between the at least one metallic layer (101) and the at least one first functional layer (103) and/or the at least one second functional layer (105) in order to enhance the contact and thereby result in the substance-locking property. A laminate component (1) structured in this way, is capable of being processed with well-known processes like deep drawing and the like without a delamination of the first or second functional layers (103, 105) from the metallic layer (101).

The intermediate layer between the at least one metallic layer (101) and the at least one first functional layer (103) and/or between the at least one metallic layer (101) and the at least one second functional layer (105) may formed from polyacrylic acid and/or copolymers of acrylic acids and/or copolymers from maleic acids

In a very particular embodiment of the present invention, the at least one first functional layer (103) and/or the polymeric component (3) comprises at least one polyamide. Therein, the first functional layer (103) and the polymeric component (3) may comprise different polyamides.

The at least one polyamide can be selected from a group comprising PA6, PA66, PA6/66, PA66/6, PA6T/6, PA6.10, PA6.12, PA12; PA9T, PA61/6T, PA6T/61, PA6/6.36 or combinations thereof. The functional layer (103) and/or the polymeric component (3) may also contain a homo polymer or a copolymer of ethylene, propylene and/or α-polyolefins and/or acrylic acid esters and/or acrylic acid and/or maleic anhydride. These copolymers may be grafted with maleic anhydride.

In a specific further development of this embodiment, the at least one first functional layer (103) comprises at least in part a laser-absorbing filler material (107). The laser-absorbing filler material (107) can be distributed as particles within the first functional layer (103) at least in those regions to which the polymeric component (3) is to be joined. Suitable laser-absorbing filler material (107) can be selected from carbon black, organic and/or inorganic pigments and dyes. An overview of laser-absorbing filler material (107) applicable according to the present invention can be found in WO 94/12352 A1 (cf. page 5, line 10, to page 7, line 26).

In a second aspect of the present invention, the above-mentioned task is solved by a metal-polymer hybrid part which is obtainable by the invented method as detailed above.

The invented metal-polymer hybrid part generally possesses the same advantages as the method of its manufacture.

In a third aspect, the present invention is related to a laminate component (1) comprising
at least one metallic layer (101) and
at least one first functional layer (103) covering the at least one metallic layer (101), wherein the at least one first functional layer (103) comprises at least in part a laser-absorbing filler material (107).

The metallic layer (101) and the at least one first functional layer (103) had been defined in detail above, why the same applied here.

By the inventive laminate component (1) a semi-processed part is provided which is designed to be joined with similar laminate components or polymeric components in order to construct hybrid parts.

In a further development of the invented laminate component (1), it comprises at least one second functional layer (105) covering the at least one metallic layer (101) opposite to the at least one first functional layer (103).

By means of this further development it becomes possible to join a polymeric component (3) on either side of the laminate component (1) so as to construct also complex structures.

The at least one first functional layer (103) may be produced by common thermoplastic production techniques (e.g. by a casting calender) and may then be laminated onto a metal or plastic surface (coil coating line or hot press, interval hot press, double belt press).

In a preferred embodiment of the laminate component (1), the at least one first functional layer (103) and/or the at least one second functional layer (105) comprises polyamide. Details have already been given above, which apply here as well.

It is preferred for the laminate component (1) that the at least one metallic layer (101) is in substance-locking contact with the at least one first functional layer (103) and/or the at least one second functional layer (105).

Since the joint between the layers is substance-locking, the invented laminate component (1) become capable of being deep-drawn without any delamination, which opens a wide variety of applications.

In a particular embodiment of the laminate component (1), the at least one metallic layer (101) exhibits functional properties. Thereby, the invented laminate component (1) or a metal-polymer hybrid part comprising this invented laminate component (1) can be enabled to take over functionalities. For instance, the functional properties comprise an EMI shielding (EMI: electromagnetic interference), a heat dissipation and an abrasion protection.

The laminate component (1) according to the invention as described above is preferably obtainable by the steps of.
i) providing at least one metallic layer (101), optionally provided with a bonding agent,
ii) heating the at least one metallic layer (101),
iii) providing at least one first functional layer (103) onto the heated at least one metallic layer (101), preferably by an extrusion process,
iv) pressing the at least one first functional layer (103) together with the heated at least one metallic layer (101) and
v) obtaining the laminate component (1).

With the process described above, laminate components (1) of metallic and polymeric plastic layers can be produced in existing continuous processes. The functional layer (103) can be extruded as a rolled good, stored if necessary, and then laminated onto the surface of the metallic layer (101) in a coil coating line.

Finally, a very specific aspect of the present invention refers to a composite component (1000), comprising
a laminate component (1) according to the present invention and as detailed above,
a polymeric component (3) joined onto the at least one first functional layer (103),
an additional component (1001) provided on the at least one second functional layer (105) opposite to the at least one first functional layer (103).

In this alternative development of the present invention, the possibility is opened to add further elements on the opposite side of the metallic layer (101), which may be for instance strengthening/reinforcing ribs or further functionalities like a polymeric foam layer.

Further aims, features, advantages and possible applications result from the following description of preferred embodiments not restricting the invention by means of the figures. All described and/or pictorially depicted features, on their own or in any combination, form the subject matter of the invention, even independently of their summary in the claims or their retrospective relationship. In the Figures

FIG. 1 depicts a schematic drawing of the laminate component (1) and a polymeric component (3) according to one embodiment of the present invention,

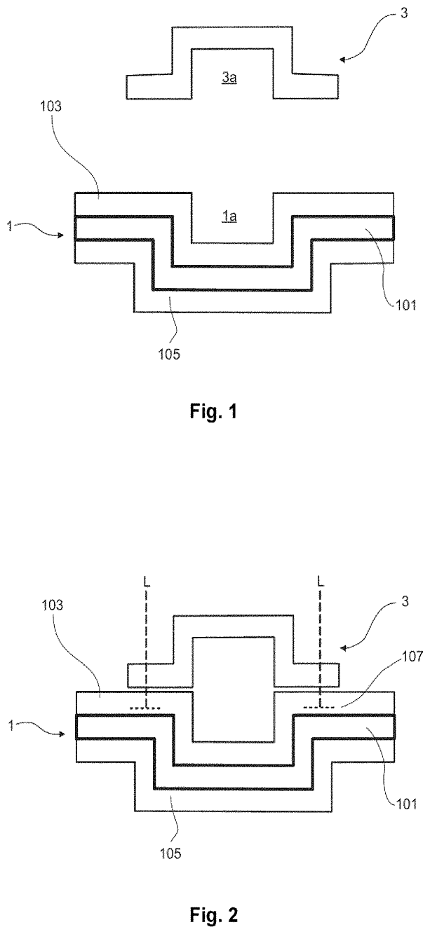

FIG. 2 depicts a schematic drawing of a joining step between the laminate component 1 and the polymeric component (3),

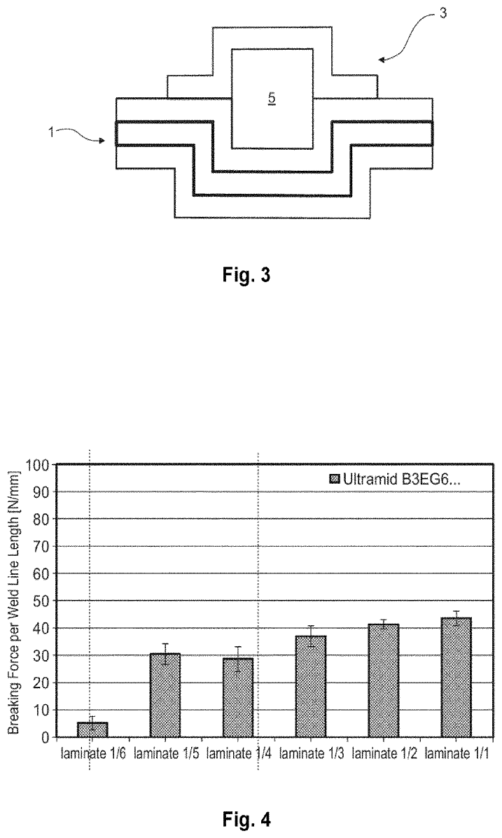

FIG. 3 depicts a schematic drawing of the metal polymer hybrid part according to a preferred embodiment of the present invention and

FIG. 4 depicts a graph showing the Breaking Force per Weld Line Length [N/mm] for the laminate components 1 of the present invention.

In FIG. 1 at the lower part a laminate component 1 according to one embodiment of the present invention is depicted. A metallic layer 101 is covered by a first functional layer 103 on the top and is covered with another second polymeric 105 on the bottom. The overall laminate component 1 has been formed into a three-dimensional structure which is depicted as a cross section in FIG. 1. Within this overall structure, the first cavity 1 a is formed.

In the upper part of FIG. 1 the polymeric component 3 is shown which is as well embodied as a three-dimensional structure depicted in the cross section, which comprises a second cavity 3a.

In FIG. 2 a schematic overview of a particular joining step is given, wherein the laminate component 1 is joined with the polymeric component 3. Within the first functional layer 103, at least in those parts to be joined with the polymeric component 3, a laser absorbing filler material 107 is distributed. The polymeric component 3 has at least in its outer regions a laser transmitting property such that the laser beam L is transmitted via those parts of the polymeric component 3 and hits the laser absorbing filler material 107. This laser absorbing filler material (107) absorbs the energy of the laser beam L and transforms the same into heat. By this heat, the polymeric material of the first functional layer 103 is at least softened or even melted and at least softens or even melts the polymeric material of the polymeric compound 3 being in contact therewith.

In FIG. 3 the result of the joining step of FIG. 2 is depicted, wherein the polymeric component 3 is substance-locking joined with the laminate component 1 thereby enclosing a hollow space 5.

The ratio of the metallic layer 101 and the first functional layer 103 in the laminate component 1 can vary in terms of both thickness and surface coverage. The material type or properties are set in relation to the function in the invented metal-polymer hybrid part and the processing/joining process.

The metallic layer 101 in particular serves for formability, mechanical properties, electro-magnetic properties and/or heat conduction/heat dissipation.

The first functional layer 103 (as well as the polymeric component 3) serves for mechanical properties, absorption capacity for lasers, electromagnetic properties, surface properties and/or chemical resistance and the like.

For the production of electronic housings, the following laminate configurations are particularly relevant:
total thickness of the laminate component 1: 0.06 mm-4.0 mm wherein the metallic layer 101 has a thickness of 0.01 mm-2.0 mm and the first functional layer 103 has a thickness of 0.05 mm-1.0 mm
metals: aluminium alloy, soft deep-drawing steels (DC)
lamination of the first and second functional layers 103, 105 on both sides of the metallic layer 101

The laminate component 1 in accordance with the present invention can be produced by all methods known to the expert. Preferably, the laminate component 1 is manufactured in a continuous process. Preferably, the laminate component 1 according to the present invention is manufactured in a process comprising the following steps:
I providing a first functional layer 103 of a polymer composition (PC) comprising the components
   Ia) at least one polyamide and/or one TPU
   Ib) may contain a C₂₌-C₂₀ alkene,
II heating a first plate of the metallic layer 101,
III pressing of the heated first plate from step II with the first functional layer 103 provided in step I while maintaining the laminate component 1.

The C₂-C₂₀ alkene mentioned above in particular may contain homopolymers or copolymers of ethylene and or acrylic acid esters and/or acrylic acid and/or α-polyolefins and/or maleic acid anhydride and/or styrene and/or propylene, homopolymers of propylene. The homopolymers and copolymers can be grafted with 0.1%-1.0% of malic anhydride.

For the polymer composition (PC) in the process according to the invention, the previously methods for providing a first functional layer 103 of a polymer composition (PC) are known to the professional as such. Preferably, the first functional layer 103 in step I is provided by an extrusion process.

Suitable extrusion processes for providing the first functional layer 103 from the polymer composition (PC) are known to the skilled person and are, for example, casting processes, calendering processes, blowing processes or multiblowing processes.

### EXAMPLES

Production of the Laminate Components 1

The polymers listed in Table 1 were compounded with a ZE 25A UXTI twin-screw extruder in the quantities shown in Table 1 to form cylindrical pellets. A first functional layer 103 was then extruded from the pellets. In the extrusion step, the quantities of carbon black masterbatch listed in Table 2 were added. The first functional layers 103 have the thickness defined in Table 2 and a width of 40 cm. The quantities given in Table 1+2 are each in weight %.
P1: polyamide 6 (Ultramid B24N of BASF SE)
P2: PA6/6.36 (Ultramid Flex F29 of BASF SE)
Co1: Lucalen A2540 D (Basell); ethylene/n-butylacrylate copolymer
Co2: Exxelor 1801 (Exxon Chemicals); maleic anhydride grafted copolymer of ethylene and propylene
Co3: ethylene carboxylic acid copolymer (Luwax EAS 5 of BASF SE)
A1: Irganox B 1171 2×20KG 4G
A2: talcum
R1: carbon black masterbatch 30% in PA6

TABLE 1

| | | PC1 | PC2 |
|---|---|---|---|
| P1 | [wt.-%] | 59.1 | |
| P2 | [wt.-%] | | 86.1 |
| Co1 | [wt.-%] | 25 | |
| Co2 | [wt.-%] | 15 | 10 |
| Co3 | [wt.-%] | | 3 |
| A1 | [wt.-%] | 0.5 | 0.5 |
| A2 | [wt.-%] | 0.4 | 0.4 |

TABLE 2

| | | first functional | first functional | first functional | first functional |
|---|---|---|---|---|---|
| | | layer 103/1 | layer 103/2 | layer 103/3 | layer 103/4 |
| PC 1 | [wt.-%] | 100 | 100 | 97 | |
| PC 2 | [wt.-%] | | | | 100 |
| R1 | [wt.-%] | | | 3 | |
| thickness | | 1000 | 400 | 100 | 400 |
| [μm] | | | | | |

The first functional layers 103 described in Table 2 are then pressed together with pre-treated metallic layers 101 to form the laminate components 1. The laminate components 1 are cut to the dimensions of 300 mm×200 mm.

The temperatures and holding times given in Table 3 were used. Laminate components 1 are produced, wherein the metallic layers 101 are briefly designated as layer 101, and wherein the functional layers 103 are briefly designated as layer 103/1, 103/2 and so on.

The structure of the laminate components 1 is described in Table 3, wherein the laminate components 1 are briefly designated as laminate 1/1, laminate 1/2 and so on.

As the metallic layers 101 a galvanized steel pretreated with Gardobond (aqueous solution of phosphoric acid and acrylic acid solution, tradename of Chemetal GmbH) having a thickness of 250 μm has been used.

The laminate components 1 were manufactured as follows. Of the first functional layer 103 sheet 1 and sheet 2 (if any) were laid in sequence on the metallic layer 101 and were then pressed in a hot press using appropriate spacers for 60 s at 250° C. Sheet 1 is always in direct contact with the metallic layer 101. The target thickness is defined by using appropriate spacers (sheets), excess polymer is removed after the pressing process.

TABLE 3

| | laminate | laminate | laminate | laminate | laminate | laminate |
|---|---|---|---|---|---|---|
| | 1/1 | 1/2 | 1/3 | 1/4 | 1/5 | 1/6 |
| metallic | layer | layer | layer | layer | layer | layer |
| layer 101 | 101 | 101 | 101 | 101 | 101 | 101 |
| sheet 1 | layer | layer | layer | layer | layer | layer |
| of first | 103/1 | 103/2 | 103/2 | 103/4 | 103/2 | 103/3 |
| functional | | | | | | |
| layer 103 | | | | | | |
| sheet 2 | layer | layer | layer | layer | layer | — |
| of first | 103/3 | 103/3 | 103/3 | 103/3 | 103/3 | |
| functional | | | | | | |
| layer 103 | | | | | | |
| total | 700 | 600 | 500 | 400 | 400 | 300 |
| thickness | | | | | | |
| of laminate | | | | | | |
| component | | | | | | |
| 1 [μm] | | | | | | |

The laminate components 1 obtained were cut into strips of 30 mm×60 mm and joined together with a glass fibre reinforced PA6 (Ultramid B3EG6 UN from BASF SE) by laser contour welding. The test specimens of the glass fibre reinforced PA6 were produced by injection moulding and had the dimensions 30 mm×60 mm×2 mm.

In FIG. 4, a graph is depicted which shows the Breaking Force per Weld Line Length [N/mm] for the laminate components 1 obtained according to the present invention.

The laser welding equipment was set es follows:

| | |
|---|---|
| Model | FOBA DP50 |
| Laser | Nd: YAG, diode pumped |
| Wavelength | 1,064 nm |
| Power | 50 Watt |
| Scan Speed | 1-15,000 mm/s |

The Contour Laser Welding was carried out with following parameters:

| | |
|---|---|
| Laser Power P [W] | 30 |
| Scan Speed v [mm/s] | variable |
| Number of Scans n (Contour Laser Welding] | 1 |
| Meltdown s [mm] (Quasi Simultaneous Laser Welding) | / |
| Clamp Pressure p [MPa] | 0.2 |
| Distance to Focus z [mm] | −50 |

The focus diameter in the joining level without the transmitting part d_{F} was appr. 2.7 mm.

### REFERENCE SIGNS

1 laminate component
101 metallic layer
103 first functional layer
105 second functional layer
107 laser-absorbing filler material
3 polymeric component
5 hollow space
L laser beam

1. A method for manufacturing a metal-polymer hybrid part, comprising the steps of
a) providing a laminate component containing at least one metallic layer covered by at least one first functional layer,
b) providing a polymeric component,
c) bringing into contact the polymeric component with the at least one first functional layer of the laminate component,
d) joining the polymeric component onto the at least one first functional layer by physical treatment, and
e) obtaining the metal-polymer hybrid part,
wherein the at least one metallic layer of the laminate component is covered by at least one second functional layer opposite to the at least one first functional layer, and
wherein the at least one metallic layer is in substance-locking contact with the at least one first functional layer and/or the at least one second functional layer, obtained by providing an intermediate layer between the at least one metallic layer and the at least one first functional layer and/or the at least one second functional layer.

2. The method according to claim 1, wherein the physical treatment comprises laser transmission welding, ultrasonic welding, friction welding and/or thermal melt joining.

3. The method according to claim 1, wherein the material of the polymeric component is at least in part translucent, and the physical treatment comprises laser transmission welding.

4. The method according to claim 3, wherein the laminate component exhibits at least in part a laser-absorbing property.

5. The method according to claim 1, wherein in step d) a joint between the laminate component ROM and the polymeric component is formed, wherein the joint is at least in part substance-locking.

6. The method according to claim 1, wherein the at least one first functional layer and/or the polymeric component comprises at least one polyamide.

7. The method according to claim 1, wherein the at least one first functional layer comprises at least in part a laser-absorbing filler material.

8. A metal-polymer hybrid part obtainable by the method according to claim 1.

9. A laminate component ROM, comprising
at least one metallic layer and
at least one first functional layer covering the at least one metallic layer,
wherein the at least one first functional layer comprises at least in part a laser-absorbing filler material.

10. The laminate component according to claim 9, further comprising at least one second functional layer covering the at least one metallic layer opposite to the at least one first functional layer.

11. The laminate component according to claim 9, wherein the at least one first functional layer and/or the at least one second functional layer comprises polyamide.

12. The laminate component according to claim 9, wherein the at least one metallic layer exhibits functional properties.

13. A composite component, comprising
a laminate component according to claim 10,
a polymeric component joined onto the at least one first functional layer, and
an additional component provided on the at least one second functional layer opposite to the at least one first functional layer.

14-15. (canceled)

16. The method according to claim 1, wherein the material of the polymeric component is at least in part laser-transmitting, and the physical treatment comprises laser transmission welding.
